(19) United States
(12) Patent Application Publication
(10) Pub. No.: US 2007/0087572 A1
(43) Pub. Date: Apr. 19, 2007

(54) Method and apparatus for the improvement of material/voltage contrast

(76) Inventors: Erwan Le Roy, Newark, CA (US); Mark A. Thompson, Austin, TX (US); William B. Thompson, Los Altos, CA (US)

Correspondence Address: Deborah Wenocur;C/o Shelly Garrett, Credence Systems Corporation, 1421 California Circle, Milpitas, CA, 95035, US

(21) Appl. No.: 11/527,434

(22) Filed: Sep. 26, 2006

Related U.S. Application Data
(63) Continuation-in-part of application No. 11/212,832, filed on Aug. 25, 2005.
Application No. 11/212,832 is a division of application No. 10/789,336, filed on Feb. 27, 2004, now Pat. No. 6,958,248.

(51) Int. Cl. H01L 21/302; H01L 21/461

(52) U.S. Cl. 438/712; 438/710

(57) ABSTRACT

A method for observing voltage contrast from buried structures in SOI. The method includes depositing a thin transparent metal layer over the BOx to dissipate charging of the oxide, and using a low FIB beam current to avoid damage due to ion implantation and direct ion beam damage.

### CROSS REFERENCE TO RELATED APPLICATIONS

This application is a Continuation in Part of copending U.S. application Ser. No. 11/212,832, filed on Aug. 25, 2005, and claims priority thereto. The specification of U.S. application Ser. No. 11/212,832 is hereby incorporated by reference. Application Ser. No. 11/212,832 is a divisional application deriving from U.S. patent application Ser. No. 10/789,336, now issued on Oct. 25, 2005 as U.S. Pat. No. 6,958,248, and claims priority thereto.

This application is further related to U.S. Provisional Applications No. 60/450,636 by Erwan Le Roy and William Thompson, filed Feb. 28, 2003, and No. 60/523,063 by Erwan Le Roy and William Thompson, filed Nov. 18, 2003, and claims priority to both of these provisional applications.

This application is further related to commonly owned U.S. application Ser. No. 10/758,146 entitled “METHOD AND SYSTEM FOR INTEGRATED CIRCUIT BACKSIDE NAVIGATION”, filed Jan. 14, 2004.

### BACKGROUND OF THE INVENTION

As IC technology advances and device dimensions decrease while circuit speeds increase, packaging and diagnostic techniques have advanced accordingly. Methods for modification and editing of circuits and devices have undergone dramatic changes, due in part to two factors. The stacking of increasingly large numbers of metal layers has limited the access to lower metal layers from the wafer frontside. In addition, the widespread use of flipchip mounting, wherein the IC is mounted face down on a packaging substrate, leaving only the backside of the chip exposed, precludes front side access to the chip. As a result of these aforementioned factors, backside signal measurement, editing, and modification of IC's has become increasingly important, using such techniques as Focused Ion Beam (FIB). The use of FIB in backside editing and repair of IC's is described by C. G. Talbot et al in commonly owned U.S. Pat. No. 6,518,571, issued Feb. 11, 2003, and by T. Lundquist et al in commonly owned U.S. patent application Ser. No. 09/738,826, filed on Dec. 15, 2000, both of which are hereby incorporated in their entirety by reference. The technique includes: 1) the global thinning of the die, 2) the optional cutting of a coarse trench (by methods such as Laser Chemical Etching or FIB), 3) milling of a smaller trench within the LCE trench to within one to a few microns of the active diffusion regions (by chemically assisted FIB), 4) FIB sputter removal or fine chemically assisted FIB milling between active diffusion regions or active devices to provide access to one or more circuit elements, and finally 5) probing, cutting, depositing, or connecting signal paths as required. This final step is interchangeably referred to as circuit modification and circuit edit.

Precise endpoint control over the milling of the smaller trench is critical to avoid damaging of active diffusion regions. Various methods of trench endpointing have been reported in the literature. By way of example, Winer et al, in U.S. Pat. No. 5,948,217 disclose a method of endpointing which is sensitive to changes in diffusion region doping chemistry, but which requires biasing of diffused regions such as n-wells with respect to the substrate.

A challenge in backside editing is navigation, i.e., locating the exact circuit node where a modification or repair is needed. To effectively and accurately access the circuit elements to be modified, both the milling of the smaller trench (also known as the “access trench”) and the fine FIB milling must be accurately positioned and registered with respect to the circuit design (CAD) and circuit elements. Various techniques have been used to create a backside image, which can be matched to the CAD layout of the chip.

A prior method for registration is IR imaging through the silicon. The IR light can pass through silicon, and optical information about the location on the chip, as well as about remaining thickness of silicon (i.e., endpoint information) is provided. This method is described in previously cited U.S. Pat. No. 6,518,571, and by E. Le Roy et al in commonly owned U.S. patent application Ser. No. 10,161,272 filed on May 30, 2002. An IR imaging and navigation system has been combined with FIB in an apparatus called IDS OptiFIB, made by NPTest, LLC. The resolution of IR imaging is limited to its wavelength, but use of an imaging process algorithm should improve corresponding CAD alignment accuracy to a fraction of one wavelength. Use of the IDS OptiFIB for CAD alignment is described in commonly owned U.S. patent application Ser. No. 10,159,527 by M. Sengupta el al, filed may 30, 2001, which is hereby incorporated in its entirety by reference.

A method known as voltage contrast, which does not utilize IR and which has been used in front-side imaging, has been recently applied in backside navigation, as described in the commonly owned U.S. patent application Ser. No. 10,274,431 by C. C. Tsao et al, filed Oct. 17, 2002, which is hereby incorporated in its entirety by reference. This method includes the biasing of n-well implanted regions with respect to the p-substrate, and shows a clear backside FIB image of the n-well regions which can be used for registration to the CAD design. However, this prior method is not effective in imaging non-biased regions. Additionally, operational complexity is introduced by this method, since a special socket for each particular device and the interconnect board to the electrical bias is required to provide the bias, and an increased knowledge level is required to know which pins should be biased relative to which others. An alternative method for registering the CAD to the FIB image for bulk Si as well as SOI devices, which did not require biasing and which could distinguish between surface and buried material regions, as well as a method to ensure accurate endpoint detection in the small trench milling, would be advantageous in through the substrate probing and circuit modification and other modifications for flip-chip mounted IC's and properly prepared wire-bonded IC's, and could additionally be utilized in obtaining vertical doping profiles for n-well characterization for failure analysis, and possibly for p-well characterization.

### SUMMARY OF THE INVENTION

It is therefore an object of this invention to provide an improved method and system for registering a CAD to the FIB image for through the substrate probing of bulk Si as well as SOI devices, without using an optical image and without requiring biasing.

It is a further object of this invention to provide an improved method of trench endpointing during the FIB milling operation with a low beam energy.

It is a still further object of this invention to provide a method for imaging of vertical doping profiles.

These objectives are met by a process and a system for implementing the process, including the use of low ion beam energies, removing the ion beam-deposited Ga layer using XeF₂, depositing a high quality insulating anti-reflection coating at low beam energy, and observing secondary electron fluctuation induced by an underneath material- or potential-contrast. This inventive process provides an enhanced voltage contrast between structures which is observable on the FIB image.

### BRIEF DESCRIPTION OF THE DRAWINGS

FIG. 1a illustrates a portion of a thinned semiconductor wafer having devices therein.

FIG. 1b illustrates the wafer of FIG. 1a having a backside ion-beam milled trench therein.

FIG. 2 is a flow chart illustrating the inventive method.

FIG. 3 is a graph of Auger results from a trench floor with and without XeF₂ treatment.

FIG. 4 is a graph of reflectance at a trench floor and of light scattering from the trench floor as a function of XeF₂ exposure time.

FIG. 5 is a graph of reflectance vs. time for oxide deposition at differing FIB beam energies.

FIG. 6 is a graph of total dose to oxide layer thickness vs. beam current density during oxide deposition.

FIG. 7a is a voltage contrast image showing n-well and p-substrate regions.

FIG. 7b is the corresponding CAD layout to FIG. 7a.

FIG. 7c is a comparison of voltage contrast with and without heat/UV treatment.

FIG. 7d is a comparison of voltage contrast with and without IR illumination during oxide deposition.

FIG. 8 is a graph of voltage contrast vs. oxide thickness for imaging beam energy of 30 keV.

FIG. 9 is a graph of voltage contrast vs. FIB magnification during imaging, following oxide deposition.

FIG. 10 is a graph of voltage contrast as a function of scan rate, after oxide deposition.

FIG. 11 is a graph of voltage contrast vs. imaging FIB beam energy after oxide deposition.

FIG. 12a is a graph of voltage contrast vs. imaging temperature.

FIG. 12b illustrates backside FIB editing of SOI devices.

FIG. 12c shows a portion of an SOI wafer with a Pt layer deposited thereon, showing structures revealed underneath.

FIG. 13 is an illustration of induced surface voltage from a single scan of a FIB beam as a function of time, for range of RC time constants.

FIG. 14a illustrates a first method for employing the present invention to provide vertical doping profile information.

FIG. 14b illustrates a second method for employing the present invention to provide vertical doping profile information.

FIG. 14c illustrates a third method for employing the present invention to provide vertical doping profile information.

FIG. 15 is a schematic diagram of an exemplary system for implementing the inventive method.

### DETAILED DESCRIPTION OF THE INVENTION

The present invention provides a method and a system for implementing the method, for inducing steady state voltage contrast between regions on an IC chip backside, so as to observe structures on a FIB image. The inventive method enables the FIB imaging without necessity of external voltage bias of the n-well regions. It further enables the use of the FIB ion beam to map the wafer from the backside, i.e., to locate positions of various materials and diffusion regions. The method is believed to be based on differential capacitive characteristics of an MOS-like structure (M=Induced Surface Conductive layer created by the beam interaction with an oxide; O=oxide; S=underlying semiconductor) which affect the secondary electron emission from the substrate. The surface of the exposed wafer backside acts as the top plate of a capacitor, a layer or feature below the surface acts as the bottom plate of the capacitor, and the intervening material or materials such as silicon or silicon oxide acts as the dielectric between the capacitor plates. The surface potential in such a capacitive situation is dependent on the potential of the material below, the local dose, the secondary electron emission coefficient of the insulator, the dielectric film quality, including trapped charge density and oxide/semiconductor interface charge density, and leakage currents (surface current and leakage in the capacitor). This in turn affects the secondary emission current, which is detected to form the FIB image. The differential in surface potential above different regions such as differing exposed or buried dopant types or concentrations, or different materials, provides a map on the FIB image. Note that, hereinafter, the terms “voltage contrast” as applied to the materials/voltage effect described herein, “materials/voltage contrast”, and “MCNC” will be used interchangeably.

The experimental results reported herein were performed using an NPTest OptiFib system. Flip-chip packaged die, having CMOS devices in a p-doped substrate, were globally thinned to less than 100 microns, and an Anti-Reflective Coating (ARC) deposited on the silicon. Die were installed into the FIB chamber, and all pins grounded. At the location where the trench was to be milled, the ARC was removed and the silicon surface was cleaned using Ga ion sputtering and ethylene di-iodide enhanced etching.

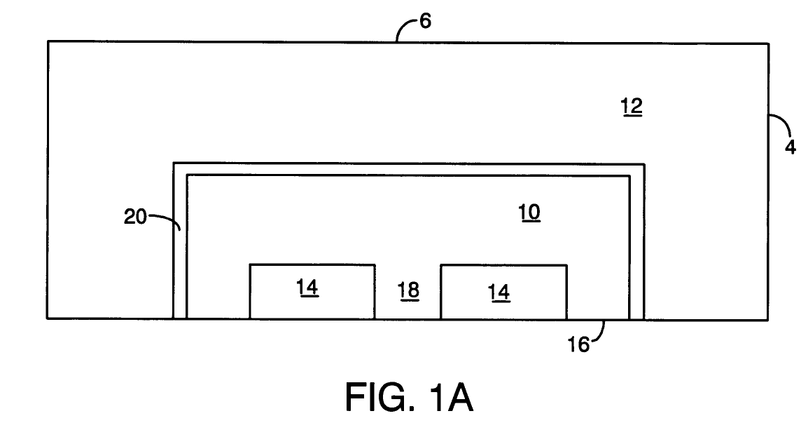

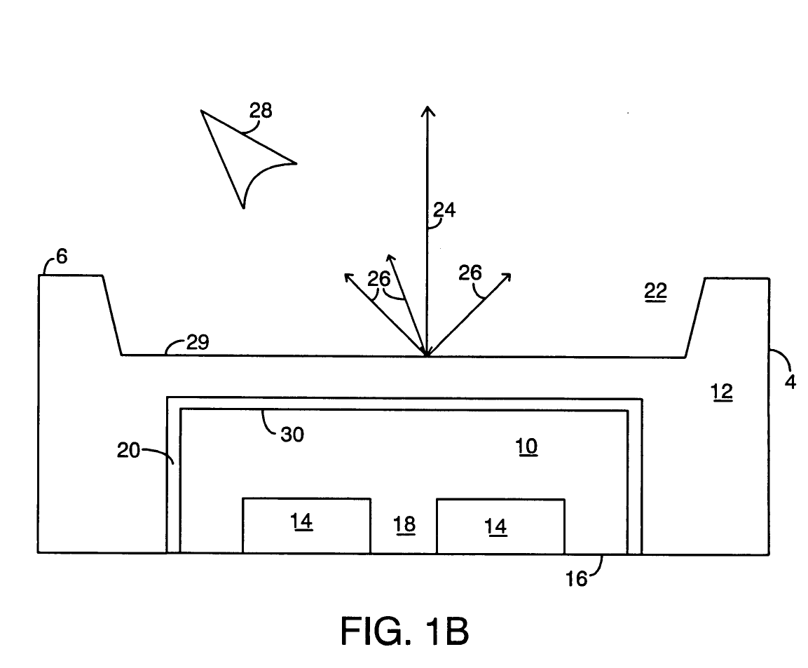

FIG. 1a shows a portion of a thinned wafer 4 with back surface 6 and with diffused regions therein. N-well region 10 is diffused into p-substrate 12. Active p-regions 14 at front surface 16 of n-well 10 have gate/channel region 18 therebetween. N-well 10 and p-substrate 12 are separated by depletion region 20, which is depleted of mobile carriers.

FIG. 1b shows the wafer 4 of FIG. 1a, with ion beam-milled trench region 22 above n-well 10 and p-substrate 12. FIB ion beam 24 (which is comprised of positive Ga ions) is scanned across trench region 22 at approximately 60 frames/sec or 30,000 lines/sec. Secondary electrons 26 are emitted, which are detected by detector 28, a scintillator/PMT assembly by way of example. The scintillator/PMT assembly detector subsystem is described in commonly owned U.S. patent application Ser. No. 09/675,981 by L. Wang et al, filed Sep. 29, 200, which is hereby incorporated in its entirety by reference. The scintillator/PMT assembly shows higher secondary electron emission regions as brighter than lower secondary emission regions.

A transient voltage contrast effect is seen as ion beam 24 mills trench region 22 such that trench floor 29 approaches sufficiently close (between 1 and 5 microns) to boundary 30 of n-well region 10. The n-well region appears brighter than the p-substrate as it is first contacted, then returns to being dark after a few imaging scans of the ion beam. By way of example, at beam current of 12 nA with a Field of View (FOV) of 350 um², the transition from bright to dark occurs after 2 imaging scans. An aspect of the present invention is the use of a low beam energy, 15 keV by way of example, to enhance this visual transient voltage contrast effect. It is believed that the lowered beam energy decreases the thickness of the ion-beam induced amorphous layer at the trench floor, and that the higher doping density of the n-well region is observed visually as a higher secondary electron yield than that of the p-substrate. The rapid transition of the n-well region from bright to dark is thought to be due to the ionization energy difference between n and p regions, created by the electric field induced by the p/n junction built-in potential. The secondary electrons emitted from the p-substrate requires less energy to reach the vacuum level than from the n-wells. The n-wells will then appear dark compared to the p-substrate.

The appearance of the transient visual voltage contrast effect can be used as a visual endpoint for use in navigating across most regions through the wafer backside.

The present invention further demonstrates a method for enabling a steady state voltage contrast to be observable on a FIB image which can be utilized to register the CAD to the FIB image without use of IR imaging, and without requiring biasing of the sample. This method includes the use of XeF₂ to remove the implanted Ga layer from the trench floor, as well as the deposition of a high quality insulator layer at low beam energy.

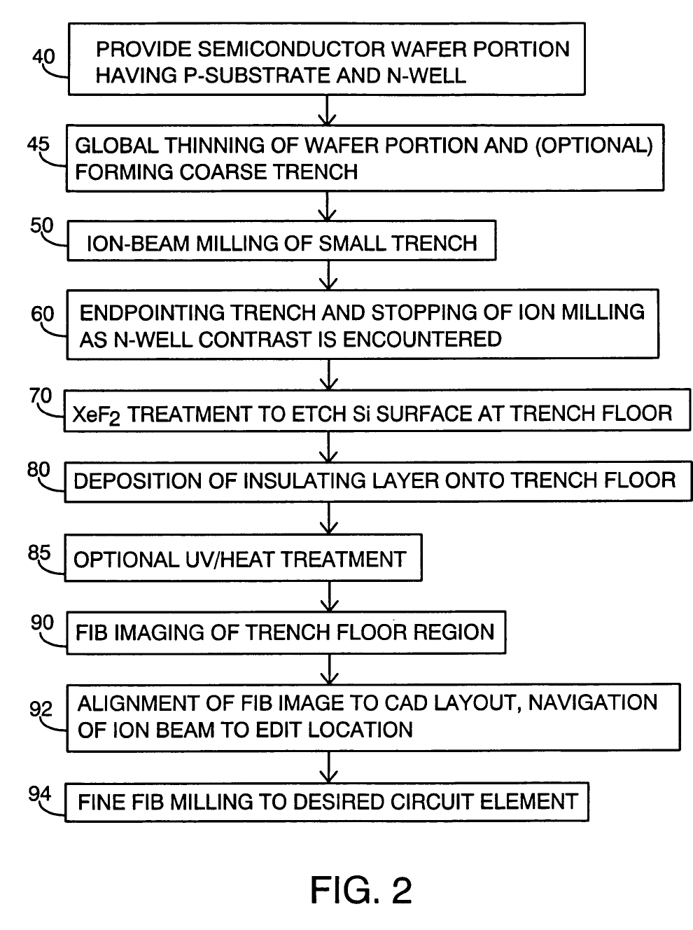

An embodiment of the invention is described below and illustrated in flow-chart form in FIG. 2. It is to be understood that the embodiment is described showing an illustrative structure comprising an n-well region in a p-substrate, but that the method can be applied to other structures without departing from the inventive concept.

In step 40, semiconductor wafer portion 4 is provided having p-substrate 12 with n-well 10 therein.

In step 45, the wafer portion 4 is globally thinned and a coarse trench cut using standard techniques.

In step 50, trench 22 is ion-beam milled using FIB ion beam 24.

In step 60, trench 22 is endpointed and ion milling stopped as the n-well contrast is encountered, which for most IC designs is approximately 2 to 4 microns from the top of the silicon or ILDO.

In step 70, implanted Ga at trench floor 29 is removed by exposing trench floor 29 to XeF₂ which spontaneously etches the surface of the Si.

In step 80, a high quality insulating layer, typically SiOₓ, is deposited at low beam energy of approximately 5 to 15 keV onto trench floor 29. Optional illumination (which may be at IR wavelengths) of the surface during insulator deposition may be utilized.

In step 85, an optional UV treatment and/or heat treatment is performed to improve the oxide quality.

In step 90, the FIB ion beam is scanned across trench region 22 and the resulting secondary electrons are detected to form a FIB image. In an embodiment, imaging is performed at a beam current of 30 keV, and a beam current of 500 pA or greater. Lower values are expected to be usable as insulating layer quality is optimized.

In step 92, the FIB image is aligned to the CAD layout and the ion beam is navigated to the precise location where editing is required.

In step 94, fine FIB milling to the desired circuit element is performed.

The global thinning and coarse trench cutting in step 45 and the ion milling of trench 22 in step 50 may be accomplished using prior techniques such as those described in commonly owned U.S. patent application Ser. No. 10/274,431 filed Oct. 17, 2002, which is hereby incorporated in its entirety by reference. The trenches can be produced by methods other than chemically assisted FIB etch, e.g. laser etch, chemical etch, mechanical micro-milling. These methods involve ex-situ processing, which is not as desirable for FIB editing.

The ion beam typically used in the milling of trench 22 (the trench typically has dimensions of about 100 microns squared to 250 microns squared), is in the energy range between 25-50 KeV, most usually 30 KeV, with a beam current in the range between 10-25 nA, most usually approximately 12-20 nA. The ion milling is generally performed in the presence of a chemical such as XeF₂ or Cl₂ for assisting in FIB material removal.

Step 60 of the present invention provides a novel method for obtaining a precise visual endpoint during the ion milling of trench 22. This visual endpoint is seen as the trench floor 29 reaches the boundary 95 between the p-substrate 12 and n-well 10. The endpointing method uses a reduced FIB ion beam voltage as the n-well is approached. At approximately 10 microns from the n-well boundary 95, which is determined by fringe contrast in the IR imaging, as described in earlier cited U.S. patent application Ser. No. 10,161,272 or using a programmable script which predicts thickness of removed silicon according to calculations of removal rate, the FIB ion beam parameters are lowered to an energy in the range between 10-15 KeV and a current of preferably 4-25 nA but extendable to a range of 2--25 nA and believed to be viable in the range of 0.4 to 50 nA. A preferred embodiment utilizes a beam current of 4 nA and a beam energy of 15 keV. These parameters have been determined to optimize the contrast, while not excessively degrading resolution of the visual image which appears as the n-well boundary is approached. The beam current density at these current and voltage values, at the standard field of view of less than 150 um², is approximately 0.2 pA/um² for a pressure of 2×10-5 Torr.

It is believed that the low beam energy minimizes the depth of an implanted Ga-induced amorphous layer formed at the trench floor 29, which allows for a clear materials contrast to be seen. The implanted Ga range is calculated to be approximately linear, with a depth (corresponding approximately to the amorphous layer thickness) of about 15 nm for 15 keV beam energy, and a depth of about 25 nm for 30 keV energy. The implantation of the Ga, however, is offset by the etch/milling rate of the Si, therefore during the chemically-enhanced milling the actual amorphous layer thickness is lower than the above. The beam current density must be held at a sufficiently low level to maintain a sufficiently high XeF₂-induced Si etch rate to prevent a build-up of a thick layer of implanted Ga at the trench floor. However, it must be sufficiently high to prevent an excessive spontaneous reaction of XeF₂ with Si, which would increase the topography of the Si surface and it is believed would increase the density of surface states. The beam current density must therefore be optimized to avoid either of these effects. A Ga implanted layer at the surface of the n-well would cause the formation of an amorphous surface which would reduce or prevent the visibility of a direct materials contrast between the n-well region and the p-substrate.

According to the present invention, the FIB ion beam milling is stopped when the visual endpoint from the transient voltage contrast described above is encountered.

An alternate enpointing method which can be used if optical capability is present is the further use of optical fringes, as described in commonly owned U.S. patent application Ser. No. 11,031,423, filed on Jan. 17, 2005, and which can indicate an endpoint 2-3 microns from the underlying structure.

Steps 70 and 80 are directed to stabilization of the voltage contrast between the n-well regions and the p-substrate regions in order to enable the formation of an optimized FIB image. This image may be registered to the CAD layout of the chip so as to navigate accurately for editing. As described above, the voltage contrast as the n-well is encountered is transient: i.e., the n-well regions appear bright at first, but darken after only a few imaging scans of the FIB beam. This is thought to be due to the implanted Ga from the imaging scans, which is not etched away since the XeF₂ flow is discontinued during the imaging scans, to avoid further etching and milling during imaging.

The formation of a steady state voltage contrast according to the present invention requires a substantially crystalline, non-amorphized Si surface at the trench floor, and a high-quality insulating layer thereon. The combination of these two components enables the imaging of a capacitively-induced (from an MOS-like structure in depletion mode) voltage contrast between n-well regions and p-substrate regions.

In step 70, XeF₂ is utilized to etch away residual implanted Ga, along with the upper non-crystalline Si layer, leaving a high quality crystalline Si surface which is substantially free of Ga.

XeF₂ etches silicon spontaneously at a high rate of about 24000 A/min at room temperature and partial pressure of 3 e15 molecules/cm³ of XeF₂, or about 8×10⁻² Torr This effect is described by J. W. Coburn and H. F. Winters in J Appl. Physics 50 (1979), 3189. It creates an SiFₓ layer and produces volatile etch products with low or even negative binding energies, which comprise mainly SiF₄, but also include Si₂F₆ and Si₃F₈. It is believed that reactions within the SiFₓ layer continue to create etch products after the XeF₂ exposure is terminated, and also that the Ga leaves the surface as a member of the SiFₓ products.

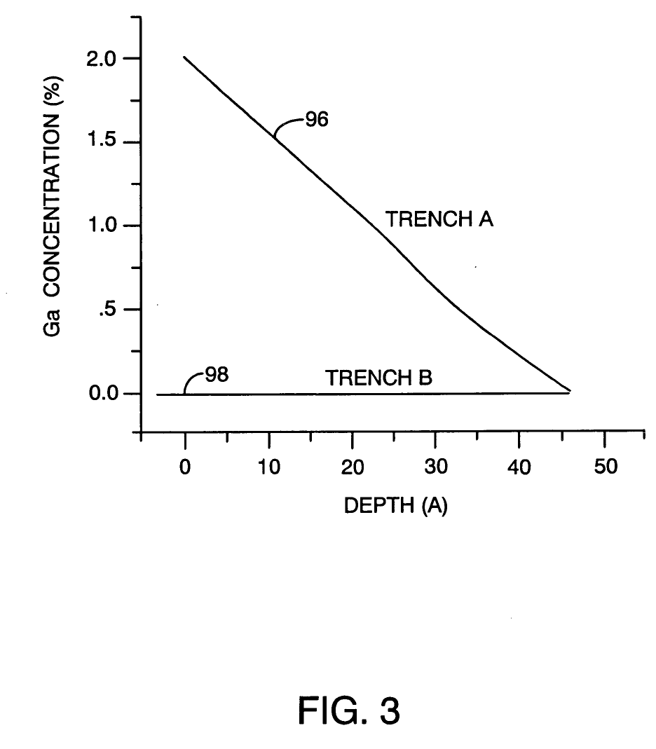

FIG. 3 shows Auger depth profiles of Ga concentration at a first trench floor (curve 96) having no XeF₂ treatment after ion milling is stopped, and equivalent Auger results from a similar second trench floor (curve 98) having 14 seconds XeF₂ exposure after ion milling is stopped. For this example, the trenches were 100 um² in area, were ion milled for 5 minutes using a XeF₂ chamber pressure of 2×10⁻⁵ Torr. Ga is detected at the first trench floor down to a depth of approximately 45 Angstroms, whereas no Ga is detected at the second trench floor, showing the effectiveness of the XeF₂ in etching away the surface Ga-containing layer. Based on the aforementioned Auger results, the spontaneous etching removed at least 45 A in 14 seconds. The etch rate under these conditions is about 193 A/min.

According to an embodiment of the present invention, step 70 comprises blanking off the FIB ion beam as soon as the voltage contrast endpoint is reached, and maintaining a chamber pressure of 2 to 5×10⁻⁵ Torr of XeF₂ for a time of 8-15 seconds, though the exposure time may be as short as 3 seconds. In a preferred embodiment, the chamber XeF₂ pressure is 2.8×10⁻⁵ Torr, and the time is 10 seconds. The local XeF₂ pressure at the die is considerably higher, estimated to be at least 8×10⁻⁴ Torr, possibly as high as in the 10⁻² Torr range. This estimate is based on the known facts that the XeF₂ etch rate of silicon is linear below 0.5 Torr XeF₂ pressure, and that the etch rate at about 0.1 Torr is 24000 A/min.

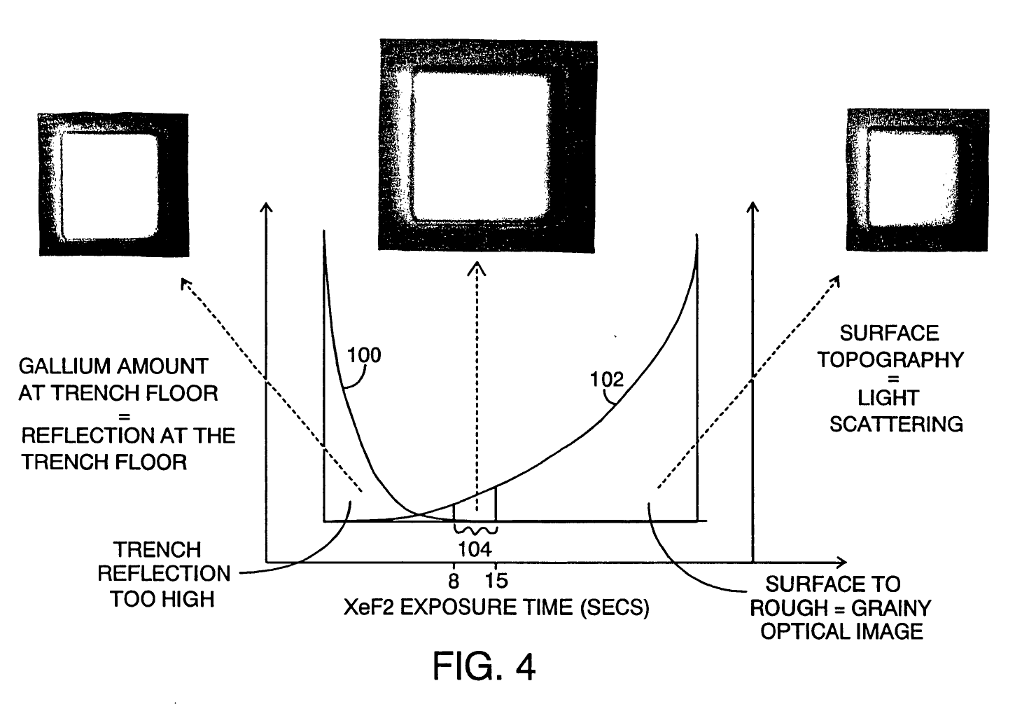

The optimum range is determined, at the lower end, by substantially complete removal of the implanted Ga. The removal of Ga is confirmed by low light reflectance at the trench floor. The higher end of the optimum range is determined by maintaining a sufficiently smooth surface topography, as confirmed by light scattering. FIG. 4 illustrates the aforementioned factors, and shows the optimal range according to the XeF₂ parameters described above to be 8-15 seconds exposure. Curve 100 shows reflectance decreasing with longer exposure, and curve 102 shows light scattering (as measured qualitatively according to the granularity of the optical image) increasing with longer exposure. Range 104 falls near the minimum of both light reflectivity and light scattering.

Following the XeF₂ exposure, the XeF₂ flow is discontinued and the system pressure rapidly drops to its baseline level in the high 10⁻⁷ Torr-low 10⁻⁶ Torr range.

In step 80 a high quality insulating layer, typically SiOₓ, is deposited by the FIB beam at low beam energy onto trench floor 29 immediately after the implanted Ga has been removed by the process of step 70. FIB oxide deposition parameters include introducing a partial pressure of a silicon oxide precursor, a silicon- and oxygen-containing compound such as Di-Butoxy-Di-Acetoxy-Silane (DBDAS). Other compounds which may be used for FIB oxide deposition include, but are not limited to: Tetraethoxysilane (TEOS), Tetramethylcyclotetrasiloxane (TMCTS), Octamethylcyclotetrasiloxane (OMCTS), Pentamethylcyclopentasiloxane (PMCPS), Dodecamethylcyclopentasiloxane (DMPS), and Tetrakis(dimethylsiloxy)silane (TDMSS). In a preferred embodiment, a partial pressure of about 2.5×10⁻⁵ Torr of DBDAS is provided for about 35 minutes at room temperature.

In an embodiment of the present invention, approximately 120-140 nm oxide, with a preferred value of 130 nm, is deposited at a beam current density in the range of 0.02-0.2 pA/um² and a beam energy in the range of 5-15 keV, with preferred values of 4 nA beam current and 15 keV beam energy. This preferred oxide thickness is equivalent to the optimal Anti-Reflective Coating (ARC) thickness. The oxide layer will therefore hereinafter be referred to interchangeably as the ARC layer. Although in the embodiment disclosed, the ARC layer is deposited in situ in the IDS OpiFIB, it is to be understood that it may be deposited or grown in other tools, alone or in combination with the XeF₂ treatment. Other possible deposition methods include but are not limited to: low temperature PVD or CVD, or spin-on.

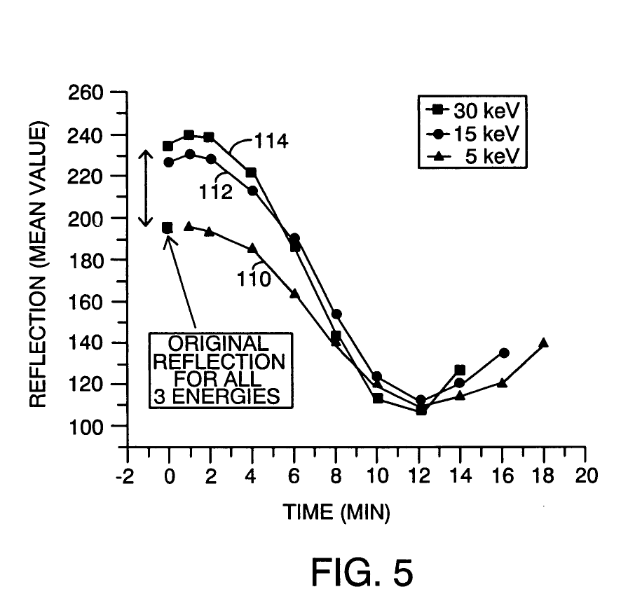

FIG. 5 shows a graph of reflectance vs. time for oxide layer deposition at differing FIB ion beam deposition energies. Curve 110 shows results for 5 keV beam energy, curve 112 shows results for 15 keV beam energy, and curve 114 shows results for 30 keV beam energy. Mean reflectance value, measured on a gray scale from 0-256 using Photoshop software, for all three energies is approximately 195 at t=0, and passes through a minimum of approximately 115 at t=12 min, corresponding to about 130 nm oxide thickness for all three depositions. Reflectance immediately jumps upward for BE=15 keV and 30 keV until about t=2 min, corresponding to about 20 nm oxide thickness, then decreases to its minimum value at t=12 min. The initial jump in reflectance indicates that for 15 keV or greater, the first approximately 20 nm of oxide film is poor quality, believed to include Ga, Si, O, and C. This poor quality is substantiated by both the FIB image monitoring during deposition and by light reflection, both of which are dependent on the chemical structure and both of which indicate that the initial layer is rich in a metallic compound, of which Ga is the only metal present.

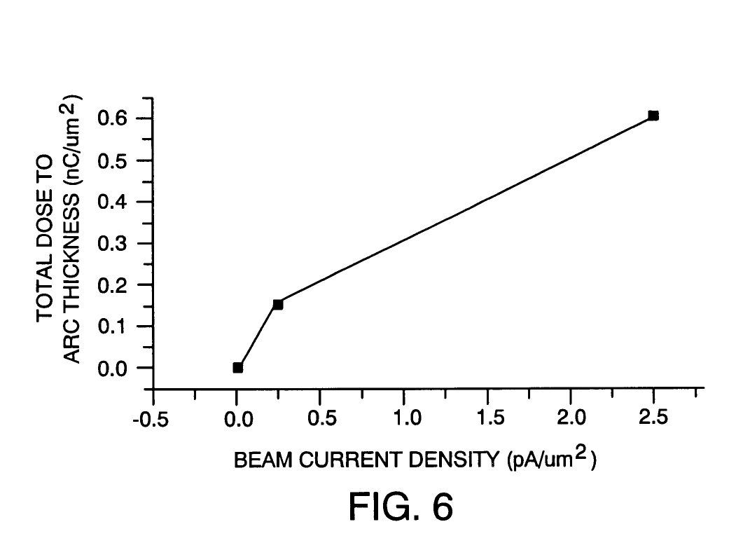

FIG. 6 shows a graph of total dose to oxide layer thickness (nC/um²) vs. beam current density (pA/um²) during oxide deposition. The best dose enhancement is seen at a low beam current density of 0.02 pA/um². This is believed to correspond to a smaller Ga concentration in the film.

Following deposition of the oxide film, DBDAS flow is discontinued and the chamber pumped down. In step 85 an optional heat treatment and/or UV treatment is performed to improve the oxide quality. A preferred embodiment utilizes a high power broadband light source, which provides UV, and a separate convective heat source at T=80C, for 5 minutes −5 hours.

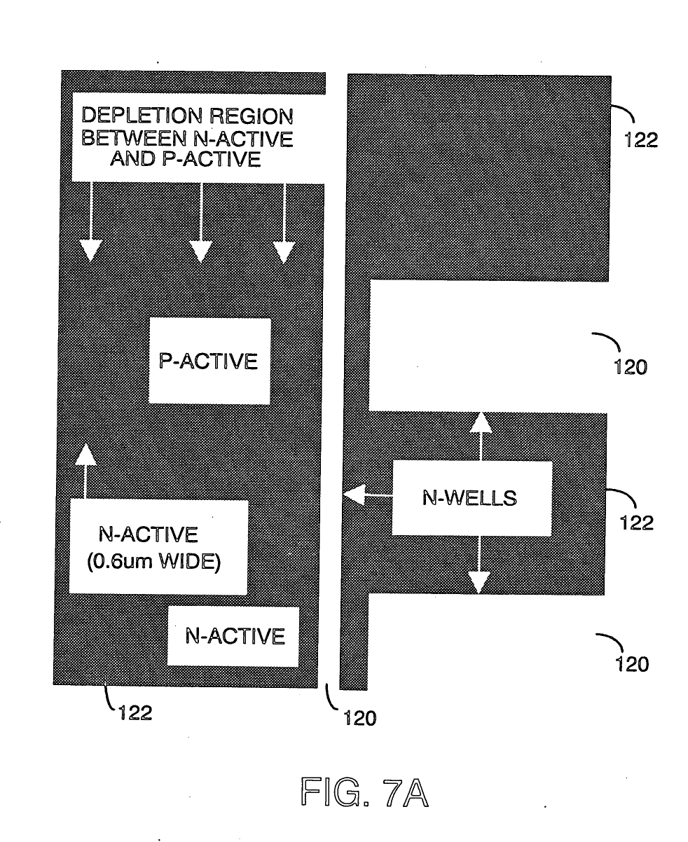

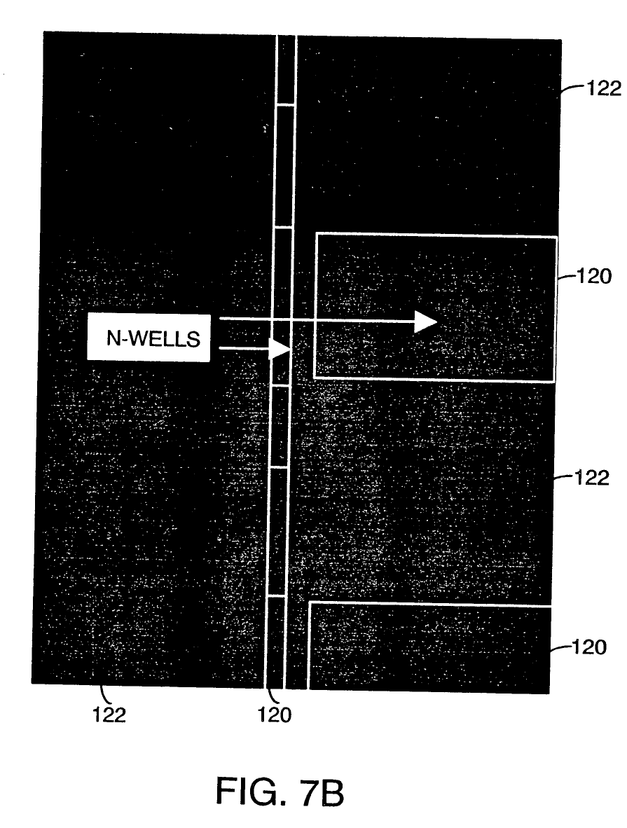

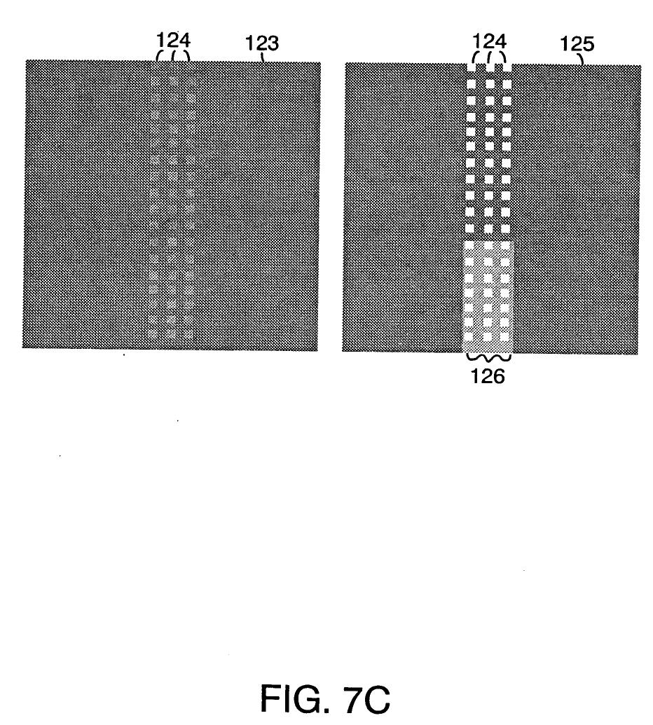

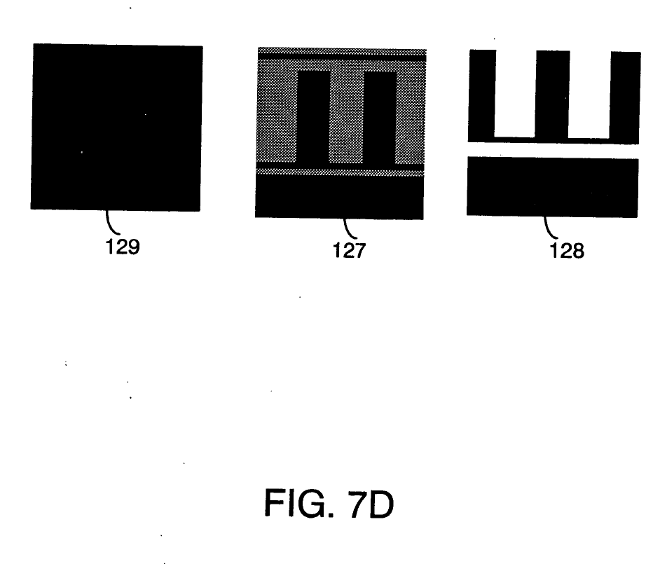

Step 90 comprises image scanning of the trench floor by the FIB ion beam. Techniques, apparatus, and controls for image scanning are described in “Coaxial Ion-Photon System” by C. C Tsao et al, Micro. Re. 41 (2001), pg. 1483, which is hereby incorporated by reference. During imaging, the sample is grounded. According to the present invention, the resulting image scan after XeF₂ treatment to remove implanted Ga and after deposition of the high quality oxide layer, results in a clear steady-state voltage contrast image of the n-well vs. p-substrate regions. FIG. 7a is a voltage contrast image, showing n-well regions 120 and p-substrate regions 122. FIG. 7b is the corresponding CAD layout, clearly showing the equivalence.

Experimental results using the heat and heat/UV treatment of step 85 have shown voltage contrast from buried structures such as poly dummies and depletion regions starting at about 5 microns above the buried structures. When the silicon above the n-well is sufficiently thin, poly gates below the diffusion regions within the n-well have also been observed.

FIG. 7c shows the improvement in voltage contrast image following heat/UV treatment. Whereas VC image 123 without heat treatment shows n-wells 124 only, VC image 125 with heat/UV for 5 hours at 70-80 degrees shows enhanced voltage contrast of n-wells 124, and additionally reveals buried dummy poly 126. Pure UV treatment without heat is found to increase voltage contrast up to 2.5 hours treatment, then to decrease it. This is thought to be due to the initial neutralization of the oxide film by generated photo-electrons, followed by the creation of net negative charge which would again decrease the voltage contrast. Pure in-situ heat treatment without UV also is found to increase voltage contrast and sharpen the image for treatment up to 30 minutes, then stays approximately level for treatment up to about 5 hours, as well as revealing buried structures. It is also believed that low temperature imaging after oxide deposition and the aforementioned heat/UV anneal will yield favorable results, due to the changing of charging/discharging dynamics.

FIG. 7d shows an improvement in voltage contrast due to illumination during oxide deposition. This is in contrast to the improvement shown in FIG. 7c, which results from heat/UV treatment following oxide deposition. The results reported herein were achieved using IR illumination (wherein the IR illumination and the FIB beam are operating simultaneously during oxide deposition), but it is expected that illumination at other wavelengths such as visible or UV will produce a similar effect. The images shown are of oxide film deposited at 6 keV energy, 0.1 pA/um² current density, over equivalent n-well structures. Imaging conditions are 6nA current, magnification of 2. VC image 127 results from no illumination during in-situ FIB oxide deposition. The oxide resistance in this case is measured as 55×10⁵ ohms-cm, and the voltage contrast value is measured as 13.6 %. VC image 128 results from illumination during in-situ FIB oxide deposition at 70% of maximum intensity, at wavelength centered at 1 um, using a 1 um filter with bandwidth of 70 nm. The oxide resistance in this case is measured as 15×10⁵ Ohms-cm, and the voltage contrast value is measured as 80%. In comparison, a PVD ex-situ deposited film yields VC image 129. Voltage contrast is very low, about 1.5%, and film resistance is higher than either of the in-situ FIB deposited films (on the order of 10¹⁰ ohms-cm). It is expected that other types of ex-situ deposited films such as CVD will yield similar results. The data shown in FIG. 7d is believed to be indicate an inverse relation between oxide resistance and voltage contrast, and to also indicate a decrease in oxide resistance with illumination during oxide deposition.

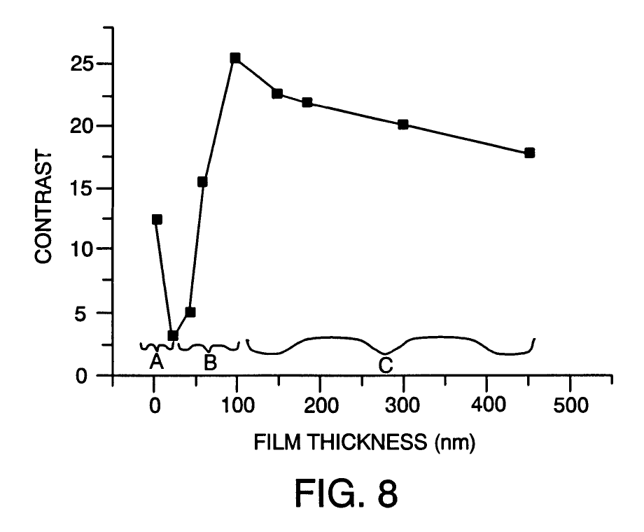

FIG. 8 is a graph of voltage contrast vs. thickness of the oxide film, for imaging beam energy of 30 keV. Voltage contrast between the p-substrate and the n-well is defined as

$$C = \frac{100 \vert {I}_{sub} - {I}_{well} \vert}{{I}_{sub} + {I}_{well}}$$

where I_{sub} and I_{well} are secondary emission from p-substrate and n-well regions respectively. Region A is dark, and the image becomes bright in regions B and C. The minimum value of contrast occurs at about 30 nm film thickness for 30 KeV beam shown in the figure. A similar graph results for beam energy of 15 keV, and the minimum contrast occurs at about 15 nm thickness for 15 keV beam. These values are believed to correspond to the concentration peak for implanted gallium at these energies. The maximum voltage contrast occurs in the range between 100 and 150 nm film thickness for both beam energies. However, oxide thicknesses in the range between 60 nm and greater than one micron have yielded significant voltage contrast.

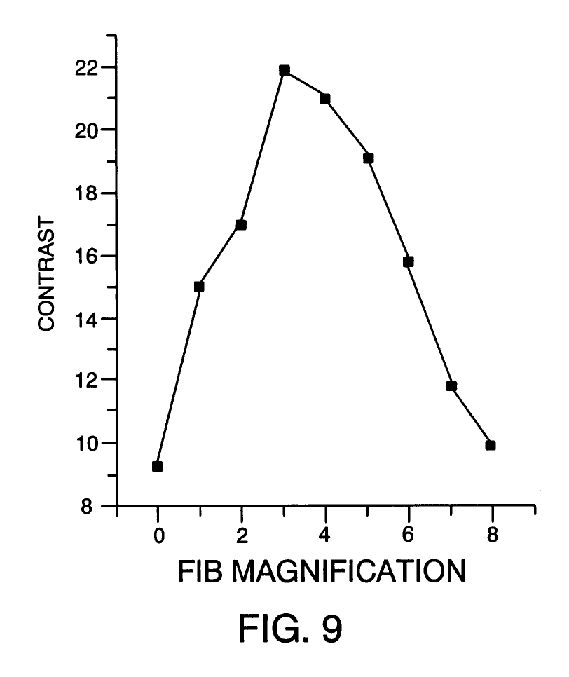

FIG. 9 is a graph of voltage contrast vs. FIB magnification during FIB imaging, following 130 nm oxide deposition. Higher magnification corresponds to a smaller field of view and therefore a higher average beam current density for constant beam current. Beam current in this case was held at 1 nA. It is seen that the voltage contrast is maximum for magnification in the range between 3 and 4, corresponding to an average beam current density of about 5-40 nA/square micron. It is believed that the contrast dependence on beam current density correlates to the contrast being enhanced when a specific dose of Ga is implanted at a location in the oxide film. It is believed that increasing the beam current density above optimal values floods the insulator surface with positively charged Ga ions and forms a conductive sheet which degrades the contrast. Too low a beam current density is believed to decrease the potential difference between different regions and lower the secondary emission current. A discussion of these mechanisms is found in E. L. Cole, “Beam-Based Localization Techniques for IC Failure Analysis”, Microelectronic Failure Analysis, Desk Reference 4^{th} ed., R. Ross, C. Boit, D Staab, editors (2001) ASM Internation, Materials Park, Ohio, pages 136-137.

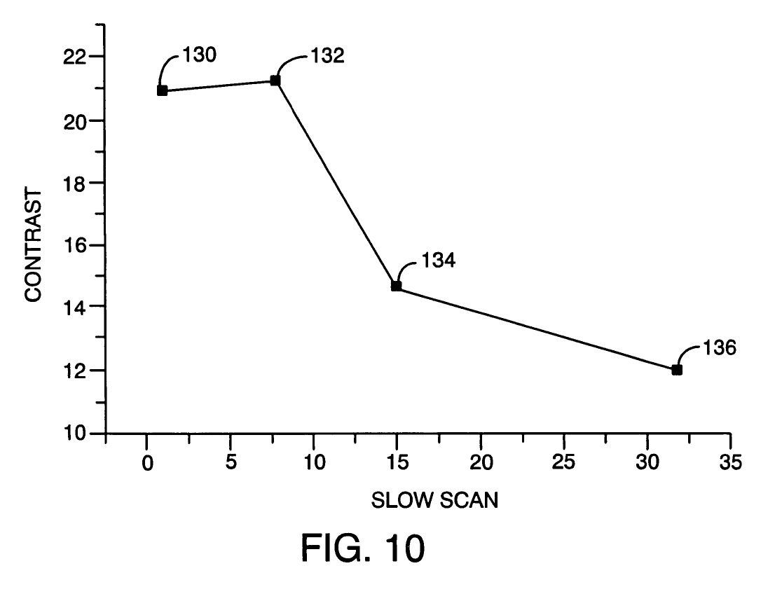

FIG. 10 is a graph of voltage contrast as a function of scan rate for 130 nm oxide deposition, with the x-axis representing factor of reduction in scan rate, with an initial value of 60 hz. Point 130 is scanned at 60 hz, point 132 at 60/8=8.5 hz, point 134 at 60/16=4.25 hz, and point 136 at 60/32=2.125 hz. Voltage contrast is seen to remain high at 8.5 hz, but to decrease sharply between 8.5 hz and 4.25 hz. The scan speed is proportional to the integrated beam current density, with a slower scan speed having a higher integrated beam current density, and thereby putting down a charge per unit area at a higher rate. It is seen that down to 8.5 hz, the leakage through the oxide layer, the trench wall, and other leakage paths can dissipate the accumulated positive charge from Ga ions between scans.

The highest imaging voltage contrast at for Field of View (FOV)=182×172 um occurs at 12 nA beam current. However, for alignment purposes, a much lower field of view is preferred, about 50 um squared. For this FOV, the image voltage contrast is the same for beam currents of 1,2,4, and 6 nA. The preferred beam current at this FOV is 1 nA, since the beam is less destructive at this value.

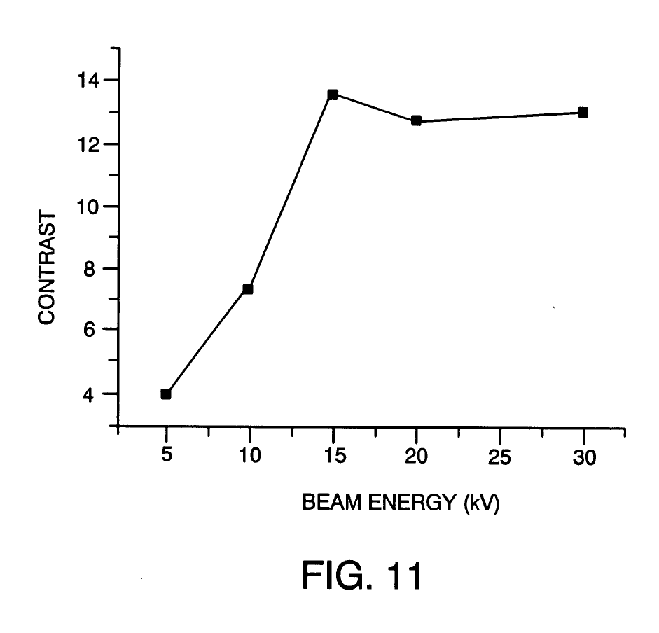

FIG. 11 is a graph of voltage contrast as a function of imaging FIB beam energy for 130 nm oxide deposition. Contrast is maximized at 15 keV, but remains high for beam energies as high as 30 keV, and greatly decreases for beam energies of 5 and 10 keV. In addition, a 15 keV FIB beam is easier to calibrate than a 10 keV beam, therefore the optimum energy range for the imaging FIB beam is 15-30 keV. Imaging beam current values range between 500 pA-20 nA.

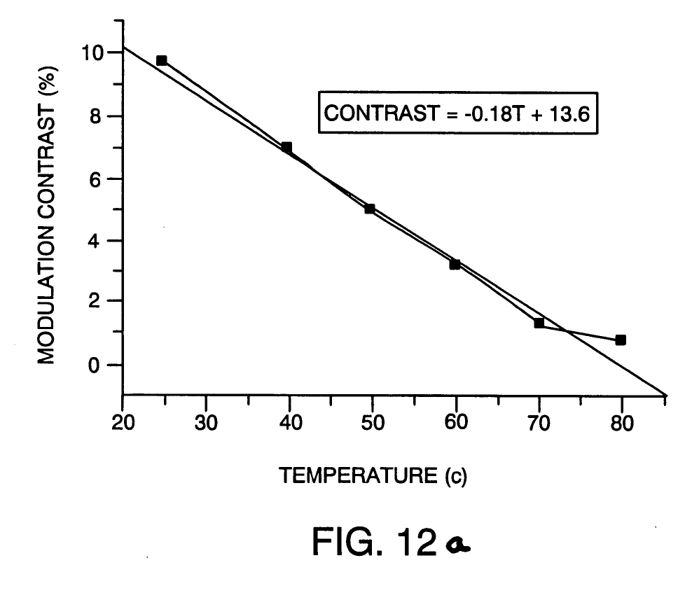

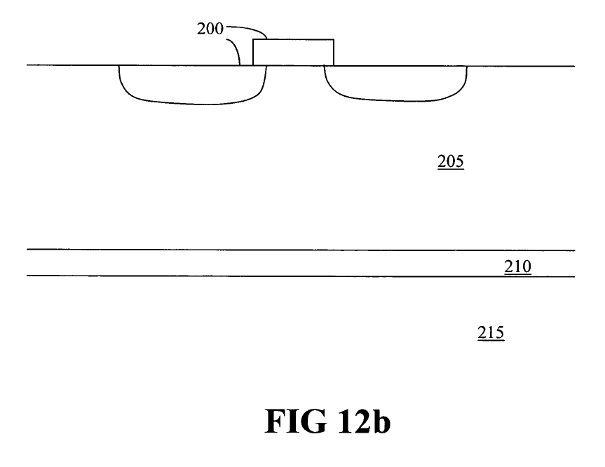

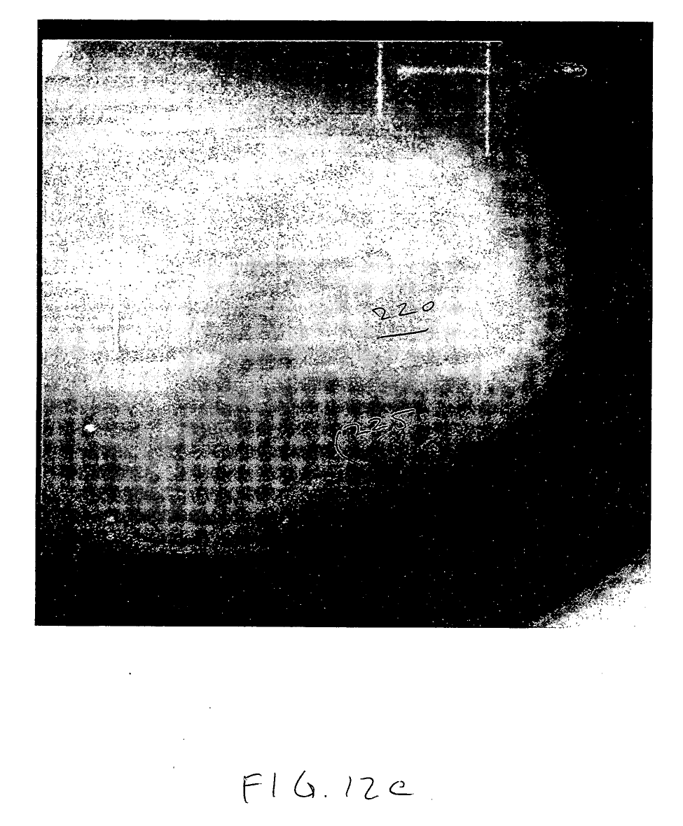

FIG. 12a is a graph of voltage contrast as a function of imaging temperature. It is seen that contrast decreases linearly with respect to temperature. The linear relation has been calculated to be
Contrast=−0.18T+13.6, where T is the temperature in degrees C.
By way of example, at T=25 C (room temperature), the capacitive voltage contrast of the imaged sample is 9.1.

Step 92 comprises aligning the FIB image with the CAD layout, and navigating to the precise location for milling of the fine FIB trench to access the desired circuit element. An embodiment of the alignment procedure is as follows:
1. CAD-OptiFIB 3-point alignment using the die corner
2. High beam current (500 pA-6 nA) and 10 pA alignment on a drawn fiducial mark (cross)
3. Local FIB-CAD alignment using VC at high beam current (>1 nA)
4. Switch to low BC (5-50 pA) and make a fiducial on the edit location
5. Switch to the high BC again, and realign the FIB to the CAD
6. Measure at high BC the offset between the cross and the edit location
7. Switch to low BC and place the box, i.e. mark the right location for the software, to electrically deflect the FIB beam to the edit location according to the measured offset
   An alternate embodiment of the alignment procedure is:

Following the CAD-OptiFIB 3-point alignment, use a voltage contrast image to locally align the CAD to the FIB at a beam current between 250 pA to 4 nA, place the target location in the center of the Field of View, and mark the surface exactly in the center by forming a spot (with the Focused Ion Beam with no dynamic deflection for a short period of time, usually 100 ms), lower the FIB beam current and configure the software to direct the FIB beam at the target location.

Step 94 comprises milling the fine FIB trench to the circuit location being edited. This method is described in “FIB Techniques to Debug Flip-Chip ICs”, by R. Livengood et al, Semiconductor International, March 1998, pg. 111.

Materials/Voltage Contrast Applied to FIB Editing on SOI

The use of FIB editing on Silicon-on-Insuslator (SOI) circuits presents some advantages, and some challenges relative to editing of bulk silicon circuits. The SOI structure is illustrated in FIG. 12b. Whereas for bulk silicon, the devices are fabricated directly into the surface of the bulk silicon wafer, for SOI the devices 200 are fabricated into an epitaxial Si layer 205 of approximately 1 micron thickness, grown on a thin (approximately 100 Angstrom thick) layer of high-quality, generally thermally grown oxide 210, known as the Bulk Oxide (BOx), generally atop the bulk silicon 215.

When doing a backside edit of a bulk silicon circuit, the endpoint for etching the smaller (200-500 micron wide) access trench (which may be produced by methods other than chemically assisted FIB etch, e.g. laser etch, chemical etch, mechanical micro-milling, all of which methods involve ex-situ processing, and are not as desirable for FIB editing) is generally reached via the materials/voltage contrast method or optical fringe method described herein, in both cases about 2-3 microns from the underlying active structures to be edited. As a result, a very high aspect ratio fine trench must be formed through the remaining silicon in order to perform the circuit edit. Among other problems which must be addressed in order to achieve this, substantial protective measures must be taken to prevent the XeF2 used as the FIB etch chemistry from laterally encroaching into the active Si regions and damaging or degrading the Si or the active devices therein. Note that etch chemistries other than XeF2 may be used, e.g., iodine-based (EDI), or chlorine-based.

In contrast, FIB editing from the backside of an SOI circuit can be accomplished similarly to frontside editing, where the deposited oxide layers protect the silicon from the XeF2 etch chemistry. For SOI, the access trench (corresponding to trench 22 described above) can be formed through the bulk silicon all the way down to the BOx layer, using methods which will be described hereinafter. Using current technology, this means that the access trench has reached to within about one micron of the active devices or layers which need to be edited. This provides several advantages, including: 1. The aspect ratio of the fine trench (also called the “access hole” which accesses the precise spot to be edited) can be lower, 2. greater alignment accuracy is possible, 3. improved optical imaging capability, as well as the ability to use visible or UV light rather than IR which images through the Si. And, since the BOx protects the silicon from damage, the XeF2 can be used for the shorter time required to form a one micron fine trench.

The access trench can extend all the way to the BOx using the following method:

The FIB beam is used to etch or mill to within a small distance of the BOx. The alignment between the FIB and the CAD can be performed without the optical image for SOI devices where the bulk oxide is already exposed by some means—although exposing the bulk oxide is highly risky unless optical methods are employed, and is likely to blow out devices. The alignment can be performed using IR techniques to see through Si, to about 1 micron accuracy. The preferred method, however, is to use an optical endpoint which is reached as follows: When the trench bottom has reached about 5-10 microns distance from the BOx layer, optical fringes, which have appeared due to destructive interference from the BOx layer, begin to increase in contrast, indicating that the endpoint is close. The spacing and tilt of the fringes also indicate the levelness of the trench bottom. These optical fringe phenomena used to determine thickness and thickness variations at a trench floor are described in commonly owned U.S. patent application Ser. No. 11,031,423, filed on Jan. 17, 2005. When the optical fringes indicate that the BOx layer is sufficiently close, preferably 2-3 microns but up to 10 microns, the FIB beam is turned off, and the XeF2 is allowed to etch off the remaining bulk silicon to expose the BOx at the trench floor. The pressure of XeF2 is generally in the range between 1 to 3×10⁻⁵ Torr as measured at a location removed from the gas nozzle introducing the XeF2 into said process chamber. Note that the transient MC/VC effect, as described earlier for the bulk Si devices, is not a strong enough effect to break into the Si through bulk oxide at a safe enough distance to use it for endpointing with an SOI structure due to the presence of the bulk oxide layer which acts as a shield from the capacitive effect seen in the bulk Si case: the trench probably would be almost to bulk oxide before the transient MC/VC effect was seen. Assuming that the trench bottom is not extremely tilted, the time required for the XeF2 to etch down to the BOx is not excessive, e.g., on the order of less than 1-5 minutes. An exposure of the BOx to the XeF2 for that duration does not cause appreciable damage to the BOx surface, although longer exposures on the order of more than 5 minutes can cause texturing of the BOx surface due to the Si content in the BOx, which may somewhat degrade the image, although no resulting device performance degradation has been observed.

Once the BOx has formed an etch stop for the access trench, the next step is to identify features underneath the oxide layer so as to properly align the FIB beam for editing. This may be done optically if the optical pathway is available, or it may be necessary or desired to perform a FIB alignment by inducing a materials/voltage contrast. A major challenge to overcome is the fact that too much scanning by the FIB beam onto the BOx can damage underlying structures via a) physical damage or electrical discharge events due to the high energy ions from the FIB beam, or b) Ga implantation into the oxide. Both of these effects can damage the underlying structures due to the very close proximity (about 1 micron) of the BOx to the active devices.

It has been found that performing a slow FIB scan can cause the formation of a transient differential charge voltage contrast image of underlying structures. The different materials underneath are believed to change the potential on the oxide surface by a capacitive effect. The effectiveness of the slow scan to bring up the voltage contrast image is related to the longer dwell time (generally 400-800 nanoseconds) at each pixel for the slow scan relative to the shorter dwell time (in the range between 50 and 200 nanaseconds, generally 100 nanoseconds) for a faster video scan. Note that the typical FIB frame contains 512×512 pixels and the scan rate can be determined using the dwell time×the number of pixels, added to the blanking time. The slow scan can have a multiple of 2×,4×,8×, etc., the dwell time of the video scan for each pixel to improve imaging; the signal is integrated over the dwell time. The improved image must be weighed against increased sputter damage which occurs as dwell time increases. The dwell time, if matched well to the frequency response of the capacitive structure, allows the capacitance and therefore the voltage contrast to build up to observable levels, and also result in a longer decay time. The resulting voltage contrast image is low resolution, showing only the structures nearest the surface. It is a capacitive effect, lasting only during the actual scan, then bleeding off within a few seconds. Note that, as mentioned earlier, the MC/VC effect is weaker for the SOI structure than for bulk silicon devices, due to the presence of the bulk oxide layer which acts as a shield from the capacitive effect seen in the bulk Si case. Therefore, for SOI structures, the slow scan and integration of the signal is required before even the transient MC/VC effect is seen.

This slow scan can only be done a very few times (depending on system parameters, one or two scans is generally acceptable) before FIB damage and Ga damage occur, and due to its transient nature, requires sharp and constant observation by the operator to detect. Often, the required alignment information cannot be obtained before damage to the devices has occurred. Unless a very fast link can be made to the CAD image immediately as the transient voltage contrast image appears, it is not greatly useful for accurately pinpointing the edit location.

An additional problem resulting from obtaining the transient voltage contrast using a slow scan is that, since there is no highly conductive medium in the vicinity, the BOx charges up from the incidence of charged ions. This causes image distortion, affecting the reliability of the edit location. If too much charging occurs, it in itself can cause damage to the underlying devices.

We have developed an inventive method which enables non-transient materials/voltage contrast imaging below the BOx layer while minimizing damage to the underlying devices.

To prevent charging of the BOx layer during FIB scanning, a very thin layer, i.e., 50-100 Angstroms, of metal is deposited onto the BOx. In a preferred embodiment, Pt is used, because Pt chemistry is already available in the OPTIFIB system. Other possible metals which could be deposited in situ in a FIB system include the carbonyl family, i.e., W, Pt, Mo, Ni, NiCo. Other metals could be used for ex-situ deposition, but there are associated disadvantages. These include but are not limited to: a) throughput issues; b) possible contamination in changing systems; c) the loss of alignment; d) addition of complexity to the overall process. At these thicknesses, the metal layer is optically transparent, so doesn't adversely affect the image, but it serves to drain charge from the oxide layer and prevent charging effects.

An embodiment of this method comprises introducing 1 to 3×10⁻⁵ Torr of methylcylopentadienyl(trimethyl) platinum into the process chamber for a short time in the presence of the ion beam. Imaging with the ion beam at a magnification and beam current low enough to distribute the dose of ions over the desired region, generally an extended area, the beam current and ion beam rastering will define where the Pt deposit will be formed, and can also control greatly the rate at which this deposition layer is formed. The desired result for observation of voltage contrast for SOI structures is an optically transparent deposited Pt layer, i.e., less than 10 nm thickness. The time necessary for Pt deposition decreases for higher beam current, but more device damage occurs as the beam current increases. Typical beam currents used for the process are about 10 pA, which necessitates about 20 seconds exposure to the gas to form the desired thickness of Pt layer.

We have found that by using this thin metal layer atop the oxide, a transfer image appears at lower beam current, for example less than 10 pA current at 30 keV voltage, compared to a beam current of about 50 pA when the slow scan without metal is performed, as described above. Using this lower beam current value has the advantages that: 1. less damage is caused to the underlying devices, both by direct ion beam damage or Ga implantation, and 2. the lower beam current is a current which can be utilized for the actual FIB edit, and therefore there may be no need to change beam parameters between the alignment and the edit.

This image is an image contrast between different materials of underlying structures. FIG. 12c shows a portion of an SOI wafer with a Pt layer deposited thereon. In corner region 220, where the Pt thickness is the lowest, i.e., less than 10 nanometers, a MC/VC image 225 of underlying features is seen.

In using this Pt-enhanced method, two advantages occur in addition to the lack of charging of the oxide layer: first, the capacitive effect of the added metal layer enhances the sensitivity to underlying structures. Secondly, the time constant of decay of the materials contrast image increases greatly with the addition of the thin metal layer. The image is stored long enough that, using the video scan mode of the FIB beam as described above, the image is always present, giving much more opportunity for the operator to correlate the image with the CAD design, and thereby accurately determine the edit location. Since the beam current is so much lower, not only is charging and associated device damage greatly minimized, but also the damage due to Ga deposition or implantation is much less of a factor.

It is expected that, if the thickness of the deposited or evaporated metal layer is too great, an EDI etch or other gas such as Cl- or Br-based etch may be used to thin it to a useful thickness.

Proposed Mechanisms

It is believed that the initial appearance of a transient voltage contrast as the n-well is encountered (using sufficiently low beam energy, along with XeF₂ chemistry during milling, to minimize the implanted Ga layer) is a direct materials contrast, wherein the higher electron donor doping density of the n-well region compared to the p-substrate produces a higher secondary electron yield. The n-well therefore appears brighter than the p-substrate. During imaging scans, when the XeF₂ flow is halted, Ga is implanted into the surface layer of both the n-well and the p-substrate. This creates a kind of p-doped surface, which, atop the n-well only, results in a p-n junction. Due to the thinness of the implanted Ga (30-60 nm) compared with the n-well thickness (about 1-2 um), the doping characteristics are those of a one-sided or hyperabrupt junction. A depletion region is formed at the junction, depleting the surface region of the n-well of mobile carriers, and lowering the secondary electron yield. Thus the n-well region becomes dark as the Ga is implanted atop the n-well.

A suggested mechanism for the creation of a steady state voltage contrast upon removal of the surface Ga layer and deposition of an oxide layer is as follows:

After removal of the surface Ga layer by the XeF₂ treatment, the n-well regions are bright, according to the materials contrast described above. As the oxide layer is deposited, the n-well region is dark for very thin oxide thickness (see FIG. 8, Region A). It is believed that in Region A the oxide thickness is less than the Ga implantation depth, and that therefore an ohmic contact exists through the oxide. The resulting depletion region as described above causes the n-well region to be dark compared with the p-substrate.

In Region B, FIG. 8, the voltage contrast changes to yield bright n-well regions. It is believed that the dark-to-bright transition occurs as the oxide thickness increases past the gallium implantation depth, the ohmic-like contact is broken, and capacitive effects begin to dominate. The presence of the FIB deposited oxide atop the semiconductor substrate, with the addition of the Induced Surface Conductive Layer (ISCL) created by the Ga ion beam, produces an MOS capacitor with a positive electrode at the top. It is proposed that the voltage contrast in this region is a Capacitive Coupling Voltage Contrast (CCVC):

Since the image is induced by a scanning FIB beam, the oxide layer acts as the dielectric of a discharging capacitor, with a dynamic signal, to generate an image of changing subsurface voltages. The scanning Ga ion beam will cause a net positive charge to build up on the surface. In addition, a bound surface charge will be produced at the ISCL when structures below the maximum beam penetration depth change potential, and the intervening material becomes polarized. The CCVC signal is the change in secondary electron yield caused by this bound potential. The contrast in CCVC images is modulated by the time constant, i.e., the time the surface of the RC circuit takes to reach equilibrium. Insulator quality (for example the insulator resistance as shown in FIG. 7d, wherein a lower insulator resistance correlates to higher VC) and leakage paths will influence the RC time constant.

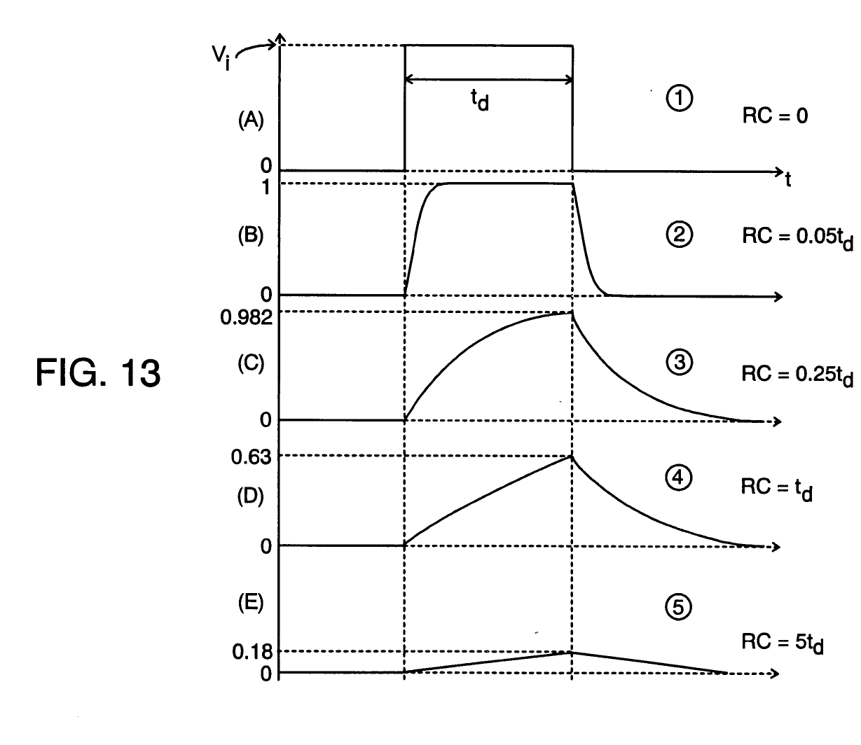

FIG. 13 illustrates the induced surface voltage from a single scan of the FIB beam as a function of time, for a range of RC time constants. Curve (a) shows induced surface voltage Vᵢ vs. t for RC=0, for a scan pulse of duration t₂ (during which secondary electrons are collected). The induced voltage is square in form, with voltage reaching a maximum value instantly, and discharging to zero voltage instantly as the scan pulse terminates. Curves (b)-(e) show the induced voltage as the RC time constant increases. The maximum amplitude of the induced voltage signal decreases, and discharge time increases.

It is believed that, since the n-well region is more heavily doped than the p-substrate, the capacitor above the n-well region will have a smaller RC time constant, and will therefore charge and discharge faster than that above the p-substrate. The p-substrate region will not fully discharge from one ion beam imaging scan pulse before the next pulse occurs, and therefore a positive charge will build up over the p-substrate, which will then appear dark on the image.

Buried structures have also been seen by voltage contrast, particularly after heat/UV treatment. This is believed to be due to their longer-range effect on the capacitive characteristics at the surface, according to a series capacitance structure.

Using the method disclosed herein, we have been able to produce a steady state voltage contrast FIB image of a FIB-milled trench floor. The image is present without sample biasing (every pin on the device is grounded), and requires no additional equipment or fixturing. N-well vs p-substrate contrast has been imaged, as well as buried dummy poly, and depletion regions between active n- and p-regions outside wells. The inventive method enables a simple, non-destructive, and accurate alignment of an integrated circuit die with the CAD layout to permit editing and other modifications to the circuit.

The method can also be used to provide vertical doping profile information, in one of several ways:

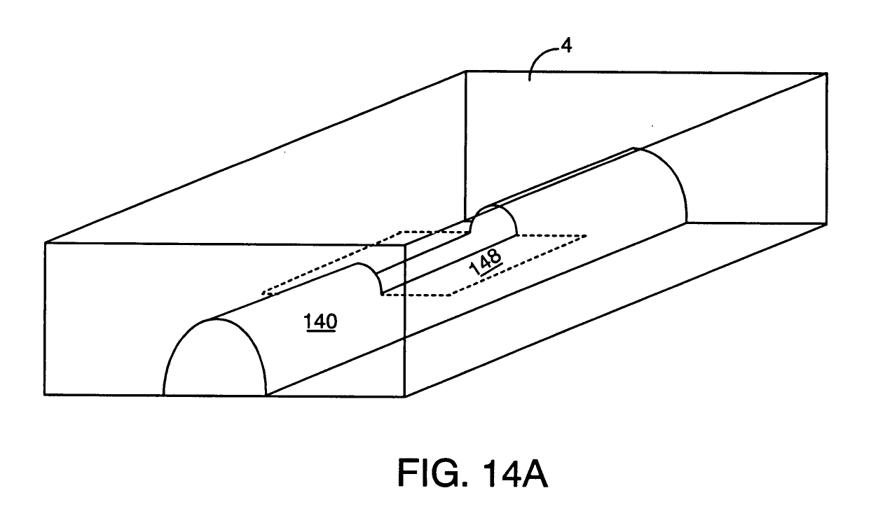

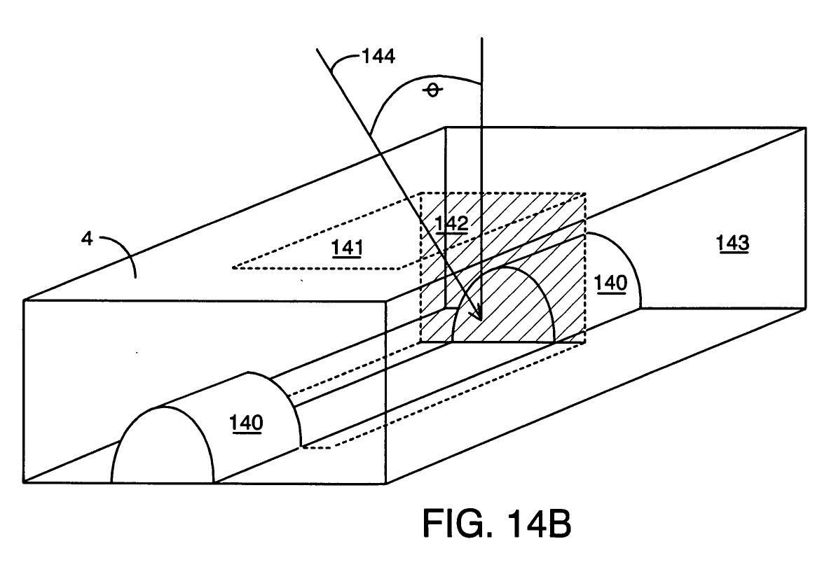

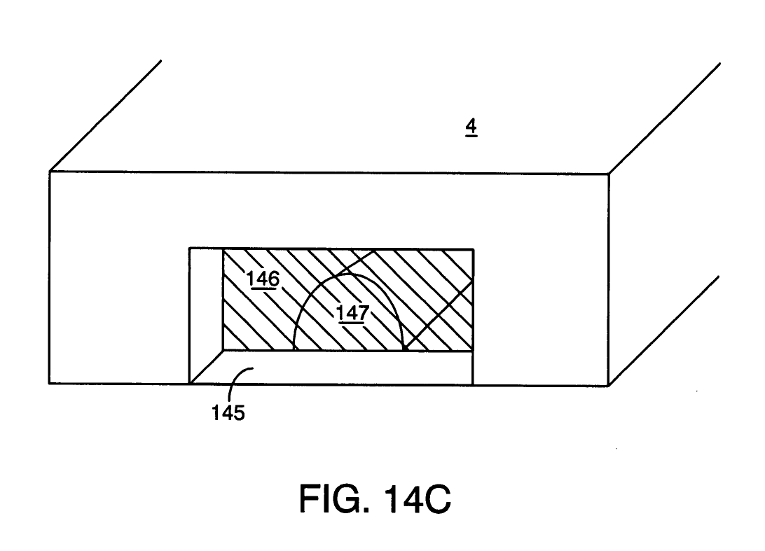

1) (illustrated in FIG. 14a) by indicating the position and size of a doped region 140 at intervals, using imaging according to the methods of the present invention, as the ion beam mills vertically through the region (the milled region 148 would necessarily encompass the doped region in at least one horizontal dimension);

2) (illustrated in FIG. 14b) by milling a vertical trench 141 all the way through the doped region 140, the milled trench encompassing the doped region in at least one horizontal dimension, such that one of the trench sidewalls 142 forms a vertical cross section near enough to the doped region to observe voltage contrast between the doped region and the surrounding region 143; then forming a non-transient voltage contrast on that trench sidewall encompassing the doped region, using the methods of the present invention, and imaging the trench sidewall using a tilted beam 144 (the trench would need to be in the range of 1-3 times wider than it is deep to enable viewing of the side wall at an angle between 70 and 45 degrees from normal);

3) (illustrated in FIG. 14c) by milling a horizontal trench 145 through a cross section of the wafer portion, the trench having a bottom surface 146 which encompasses the vertical doped region 147, until the bottom trench surface reaches the doped region, then imaging the trench bottom at the doped region using the methods of the present invention to form a non-transient voltage contrast.

System Considerations

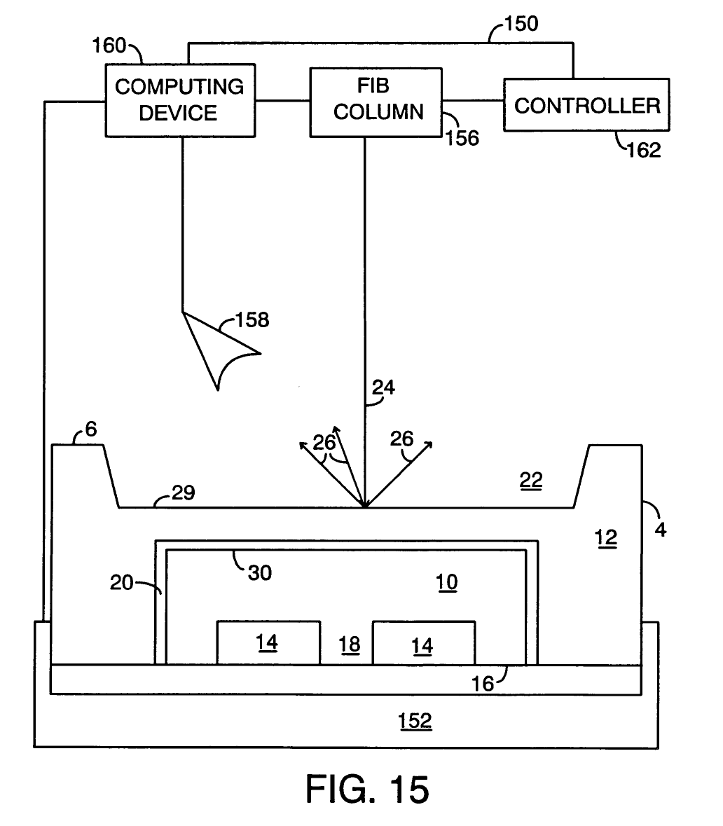

The method described herein can be implemented in one embodiment using a FIB system 150, which is illustrated in FIG. 15. The system includes sample holder 152, FIB column 156, detector 158, computing device 160, and one or more controllers 162, as well as optional thinning devices and thickness measurement devices. A description of these system components is found in previously cited U.S. patent application Ser. No. 10,274,431 by C. C. Tsao et al. In another embodiment, which includes UV and/or heat treatment of the sample, the system must include either in-situ or ex-situ heat and/or light sources.

It is to be understood that the invention described herein is not restricted to the exact embodiments described. Changes and modifications may be made without departing from the inventive concept. By way of example, the methods described can be employed with any charged particle beam, such as electron beam or ion beams of species other than Ga. The invention is further not restricted to use in backside editing: the improved quality of the insulator deposited as described herein can be used for frontside or backside circuit editing to isolate and protect exposed conductors physically, electrically, and chemically. The scope of the invention is to be construed in view of the claims.

With this in mind, we claim:

1. A method of observing materials/voltage contrast from buried structures under a surface of a Silicon On Insulator (SOI) structure having exposed oxide comprising the steps of:
depositing an optically transparent metal layer on said SOI structure; and
forming and observing a contrast in secondary emission from said buried structures upon exposure of said surface to a FIB beam.

2. The method of claim 1, wherein said optically transparent metal layer comprises Pt.

3. The method of claim 2, wherein said optically transparent metal layer has a thickness less than 10 nanometers.

4. The method of claim 1, wherein said optically transparent metal layer is formed by:
forming a metal layer having a thickness greater than desired; and
thinning said metal layer using a chemical etch.

5. The method of claim 3, wherein said optically transparent Pt layer having a thickness less than 10 nanometers is formed by:
forming a Pt layer having a thickness greater than desired; and
thinning said Pt layer using a chemical etch.

6. The method of claim 5, wherein said chemical etch is selected from the group consisting of: EDI, Cl-based etch, and Br-based etch.

7. The method of claim 1, wherein said optically transparent metal layer is formed in situ.

8. The method of claim 7, wherein said optically transparent metal layer is Pt.

9. The method of claim 8, wherein said Pt layer is formed in situ by introducing 1 to 3×10⁻⁵ Torr of methylcylopentadienyl(trimethyl) platinum for about 20 seconds over a large area in the presence of an ion beam having current approximately 10 pA.

10. The method of claim 1, wherein said step of forming and observing a contrast in secondary emission from said buried structures upon exposure of said surface to a FIB beam comprises scanning said surface with said FIB beam having a current and voltage suitable for FIB editing.

11. The method of claim 10, wherein said FIB beam has a current less than 10 pA at a voltage close to 30 keV.

12. The method of claim 10, wherein said step of scanning said surface with said FIB beam having a current and voltage suitable for FIB editing comprises performing a raster scan at pixel dwell time corresponding to video scan speed.

13. The method of claim 12, wherein said pixel dwell time is in the range between 50 nano seconds and 200 nanoseconds.

14. The method of claim 13, wherein said pixel dwell time is 100 nanoseconds.

15. The method of claim 1, further including the step of aligning said SOI structure to a corresponding CAD image according to said observed materials/voltage contrast.

16. A method of performing a backside circuit edit on an SOI structure at a specified location on an SOI sample, said SOI sample including a bulk Si layer, a bulk oxide layer on said bulk Si layer, and an epitaxial Si layer on a surface of said bulk oxide layer, said SOI structure being built in said epitaxial Si layer, said method comprising the steps of:
a) forming an access trench in said bulk Si layer from said backside of said SOI sample, said access trench encompassing said specified location;
b) halting the formation of said access trench at a user-determined distance from said bulk oxide layer;
c) removing substantially all remaining bulk Si in said trench to expose said bulk oxide layer in said trench;
d) aligning said SOI structure to a corresponding CAD image by forming a materials/voltage contrast image of said SOI structure on said bulk oxide layer surface; and
e) forming an access hole to access the precise spot on said SOI structure to be edited.

17. The method of claim 16, wherein said step of forming an access trench is performed by FIB etching/milling with a FIB system including a process chamber under vacuum.

18. The method of claim 16, wherein said step of halting the formation of said access trench at a user-determined distance from said bulk oxide layer comprises stopping at an optical endpoint determined by one of: optical interference fringes from the bulk oxide layer surface; and a visible MC/VC contrast between structures under said bulk oxide layer.

19. The method of claim 16, wherein said user-determined distance from said bulk oxide layer is in the range between 2 and 3 microns.

20. The method of claim 16, wherein said step of removing substantially all remaining bulk Si in said trench to expose said bulk oxide layer in said trench is performed using a chemical etch with the FIB beam turned off.

21. The method of claim 20, wherein said chemical etch comprises XeF2 etch.

22. The method of claim 21, wherein said XeF2 etch is performed for less than 5 minutes.

23. The method of claim 22, wherein the pressure of XeF2 is in the range between 1 to 3×10⁻⁵ Torr as measured at a location removed from a gas nozzle introducing said XeF2 into said process chamber.

24. The method of claim 16, wherein said step of forming a materials/voltage contrast image of said SOI structure on said bulk oxide layer surface comprises:
depositing an optically transparent metal layer on said SOI structure; and
forming and observing a contrast in secondary emission from said buried structures upon exposure of said surface to a FIB beam.

25. The method of claim 24, wherein said optically transparent metal layer comprises Pt having a thickness less than 10 nanometers.

26. The method of claim 24, wherein said optically transparent metal layer is formed by:
forming a metal layer having a thickness greater than desired; and
thinning said metal layer using a chemical etch.

27. The method of claim 25, wherein said optically transparent Pt layer having a thickness less than 10 nanometers is formed by:
forming a Pt layer having a thickness greater than desired; and
thinning said Pt layer using a chemical etch.

28. The method of claim 27, wherein said chemical etch is selected from the group consisting of: EDI, Cl-based etch, and Br-based etch.

29. The method of claim 25, wherein said Pt layer is formed in situ by introducing 1 to 3×10⁻⁵ Torr of methylcylopentadienyl(trimethyl) platinum for about 20 seconds over a large area in the presence of an ion beam having current approximately 10 pA.

30. The method of claim 24, wherein said step of forming and observing a contrast in secondary emission from said buried structures upon exposure of said surface to a FIB beam comprises scanning said surface with said FIB beam having a current and voltage suitable for FIB editing.

31. The method of claim 30, wherein said FIB beam has a current less than 10 pA at a voltage close to 30 keV.

32. The method of claim 30, wherein said step of scanning said surface with said FIB beam having a current and voltage suitable for FIB editing comprises performing a raster scan at pixel dwell time corresponding to video scan speed.

33. The method of claim 32, wherein said pixel dwell time is in the range between 50 nano seconds and 200 nanoseconds.

34. The method of claim 16, wherein said step of forming an access hole to access the precise spot on said SOI structure to be edited is performed using a FIB beam.
